(19) United States
(12) Patent Application Publication
(10) Pub. No.: US 2017/0063317 A1
(43) Pub. Date: Mar. 2, 2017

(54) Amplifier

(71) Applicant: U.S.A. as represented by the Administrator of the National Aeronautics and Space Administration, Washington, DC (US)

(72) Inventors: GEORGE SUAREZ, Burtonsville, MD (US); JEFFREY J. DUMONTHIER, Ashburn, VA (US)

(21) Appl. No.: 14/843,505

(22) Filed: Sep. 2, 2015

(51) Int. Cl. H03F 3/45

(52) U.S. Cl. CPC H03F 3/45179

(57) ABSTRACT

The present invention is directed to a radiation-hardened by design quad amplifier in a commercial 0.25 μm CMOS process; a 500 had total ionization dose (TID) (which degrades parts over time), and single event latchup immunity (SEL) which is greater than the linear energy transfer (LET) 120 MeV-sq. cm/mg; a single 3.3 V (range 3.0-3.6 V) power supply V_{dd} or dual power supply +/−1.65 V; four (4) channels of analog inputs; enhanced low-dose rate sensitivity (ELDRS) immunity; output rail-to-rail input/output (I/O) OPAMP which can drive resistive loads down to 1 kOhm; an active high enable pin en; a bias pin that can be used to adjust the OPAMP quiescent current; and a compact hermetic 16-lead ceramic small outline integrated circuit (SOIC) package.

### BACKGROUND OF THE INVENTION

1. Field of the Invention

The present invention relates to a compact, low power, radiation-hardened multi-channel amplifier/operational amplifier (OPAMP) application-specific integrated circuit (ASIC) for miniaturized instrument electronics.

2. Description of the Related Art

Conventional amplifiers are radiation hardened, but some have a radiation tolerance specified at 300 krad, which is not sufficient to protect against long-term radiation damage of delicate parts, or against a single catastrophic event. Further, conventional amplifiers may suffer from enhanced low-dose rate sensitivity (ELDRS), which is challenging to radiation hardness assurance, and causes significant irradiation time to examine the amplifier—causing a burden to a project's schedule and budget. Further, conventional operational amplifiers do not have adjustable current which can decrease power consumption. Finally, access to parts for space missions, including CubeSats, is difficult due to budget limitations.

Thus, an amplifier that has superior radiation tolerance, that will protect the operation of the amplifier, and yet be compact and low power, is needed.

### SUMMARY OF THE INVENTION

The present invention is directed to a radiation-hardened, space-worthy, compact, quad operational amplifier (OPAMP) multi-channel Application Specific Integrated Circuit (ASIC) to reduce the size, mass, and power of radiation-hardened instrument electronics. The ASIC features are science-driven based on applications in a realistic space environment such as housekeeping/health monitoring and instrumentation systems.

In one embodiment, an amplifier includes: a 0.25 μm complementary metal-oxide semiconductor (CMOS); a 500 krad total ionization dose and single event latchup immunity which is greater than the linear energy transfer (LET) 120 MeV-sq. cm/mg; four channels of analog inputs; enhanced low-dose rate sensitivity immunity; a bias pin used to adjust quiescent current in a range of 1-35 μA; and an active high enable pin en.

In one embodiment, the amplifier is radiation-hardened.

In one embodiment, the amplifier includes a 16-lead ceramic small-outline integrated circuit (SOIC) package in which the amplifier is disposed.

In one embodiment, the amplifier further includes a 3.0-3.6 V supply.

In one embodiment, the amplifier is a four-channel mixed-signal Application Specific Integrated Circuit (ASIC).

In one embodiment, the amplifier is a rail-to-rail input/output (I/O) amplifier which can drive resistive loads down to 1 kOhm.

In one embodiment, the amplifier further includes an open loop direct current (DC) gain of 85 decibels (dB), unity gain bandwidth of 14 MHz, and 60 degrees phase margin.

In one embodiment, the amplifier operating temperature is between −55° C. to 125° C., and is typically room temperature at 25° C.

In one embodiment, the amplifier further includes: external control of the amplifiers via said en and said bias pins.

In one embodiment, the amplifier further requires: a 1 μF and a 10 μF capacitor for said supply voltage; and one of a 1 μF or a 10 μF capacitor for said bias.

Thus has been outlined, some features consistent with the present invention in order that the detailed description thereof that follows may be better understood, and in order that the present contribution to the art may be better appreciated. There are, of course, additional features consistent with the present invention that will be described below and which will form the subject matter of the claims appended hereto.

In this respect, before explaining at least one embodiment consistent with the present invention in detail, it is to be understood that the invention is not limited in its application to the details of construction and to the arrangements of the components set forth in the following description or illustrated in the drawings. Methods and apparatuses consistent with the present invention are capable of other embodiments and of being practiced and carried out in various ways. Also, it is to be understood that the phraseology and terminology employed herein, as well as the abstract included below, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the methods and apparatuses consistent with the present invention.

### BRIEF DESCRIPTION OF THE DRAWING

FIG. 1 is a schematic drawing of an exemplary arrangement of an amplifier according to one embodiment consistent with the present invention.

FIG. 2 is a drawing of an amplifier disposed in a package according to one embodiment consistent with the present invention.

### DESCRIPTION OF THE INVENTION

The present invention is directed to a radiation-hardened, space-worthy, compact, quad operational amplifier (OPAMP) multi-channel Application Specific Integrated Circuit (ASIC) to reduce the size, mass, and power of radiation-hardened instrument electronics. The ASIC features are science-driven based on applications in a realistic space environment such as housekeeping/health monitoring and instrumentation systems.

The present invention is directed to reducing power, mass, and volume for highly resource-constrained space instruments. The main objective is to design, fabricate, and test a radiation-hardened, multi-channel, quad operational amplifier ASIC, that will enable miniaturized instrument electronics. The development includes design and fabrication of prototype chips in a commercial complementary metal-oxide semiconductor (CMOS) process.

Operational amplifiers are extremely versatile, and are the amplifier of choice for a large number of applications. The advantages of integration allow operational amplifiers to be included in many ASICs, where, combined with other circuit elements, a chip can be designed to carry out a specific function.

The apparatus of the present invention includes four (4) rail-to-rail operational amplifiers (OPAMP) with enable logic and current biasing. The OPAMPs can be set in different modes including inverting, non-inverting, summing, and unity-gain configurations, among others. All the amplifiers are enabled when en is set high, otherwise the outputs are in a high impedance state.

A single resistor from bias to V_{dd} is needed to bias the amplifiers and is used to adjust the quiescent current consumption of the amplifiers depending on the application speed requirement. Bias current increases performance and power consumption, but if a high performance is not needed, then the current can be lowered, decreasing power consumption. This is contrary to conventional operational amplifiers which are simply powered up and which are not adjustable.

Further, the amplifiers can drive resistive loads down to 1 kOhm and large capacitive loads up to several μF.

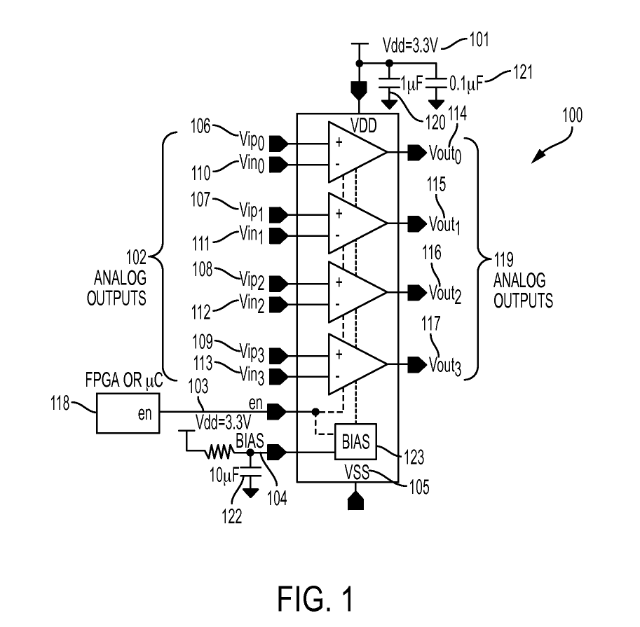

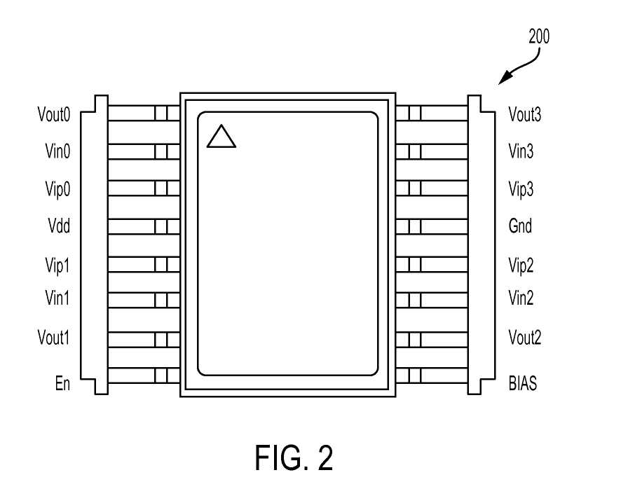

The present invention includes features such as: radiation-hardened by design quad amplifier 100 (see FIG. 1) in a commercial 0.25 μm CMOS process; a 500 krad total ionization dose (TID) (which degrades parts over time), and single event latchup immunity (SEL) (for a catastrophic event, such as a current surge), which is greater than the linear energy transfer (LET) 120 MeV-sq. cm/mg; a single 3.3 V power supply V_{dd} 101 or dual power supply +/−1.65 V; four (4) channels of analog inputs 102; enhanced low-dose rate sensitivity (ELDRS) immunity; output rail-to-rail input/output (I/O) OPAMP which can drive resistive loads down to 1 kOhm; an active high enable pin en 103; full military temperature range (−55° C. to 125° C.); an open loop direct current (DC) gain of 85 decibels (dB), unity gain bandwidth of 14 MHz, and 60 degrees phase margin; a bias pin 104 that can be used to adjust the OPAMP quiescent current; and a compact hermetic 16-lead ceramic small outline integrated circuit (SOIC) package 200 (see FIG. 2).

In contrast, as noted above, and further to the novel feature of the bias pin 104, some available conventional radiation hardened devices have a radiation tolerance specified at 300 krad, and suffer from ELDRS. Further, access to parts for low-class missions including small satellites (i.e., CubeSats), is difficult due to budget limitations.

More specifically, the quad amplifier operates as follows.

The quad amplifier 100 of the present invention is connected to a supply voltage V_{dd} (3.0-3.6 V, typically 3.3. V) 101, and a supply ground voltage Vss (−0.1-0.1, typically 0.0V) 105. Its operational temperature is between −55° C. to 125° C. (typically room temperature at 25° C.), and the storage temperature range is from −65° C. to +150° C. (typically room temperature at 25 ° C.). The maximum junction temperature is +150° C., and the lead temperature (soldering, 10 seconds), is 300° C. Thermal resistance, junction to case θ_{jc}, is 7° C/W.

The bias 123 current ranges from 1 to 35 μA; the supply current I_{dd} ranges from 2-6 mA (typically 4 mA); power is 13.2 mW, with a range of 6.6-19.8 mW; offset of 2 mV (range of −2 to 2 mV); open loop gain A_{OL} of typically 85 decibels (dB), with a low of 80 dB; unity gain bandwidth (UGBW) of typically 14 MHz (range of 12-16 mHz); and a phase margin (PM) of typically 59 degrees (range of 54-64 degrees), with a 25 μA bias, 5 kOhm and 1 pF loads). The analog mux on-resistance is 500 Ohms.

Different signals are applied to the 4 negative input pins (Vᵢₙ₀-Vᵢₙ₃) 106-109 and 4 positive input pins (Vᵢₚ₀-Vᵢₚ₃) 110-113 while the en pin 103 is set to enable and select the input that appears at the analog output pins (Vₒᵤₜ₀-Vₒᵤₜ₃) 114-117 through a CMOS switch.

The amplifier 100 of the present invention is typically operated using an external controller such as a field-programmable gate array (FPGA) or microcontroller (μC) 118 to set the en pin 103. It is recommended that sensitive analog and output signals 119 are shielded with the ASIC ground and use bypass capacitors (i.e., ceramic 1 μF capacitor 120 in parallel with a 0.1 μF capacitor 121) from V_{dd} to Vₛₛ. The bias pin 104 is also bypassed with a 1 μF or 10 μF capacitor 122.

In one embodiment, the package for the amplifier 100 of the present invention is shown in FIG. 2. The package can be presented in different configurations such as a SOIC 200 and flatpacks (SOIC). In one embodiment, the amplifier 100 is packaged in a standard 16-lead ceramic SOIC package (see FIG. 2) following MIL-STD procedures using silver glass (J7000) for die attach and 1.25 mil (wedge) aluminum wires. The SOIC 16-package can be inserted in a standard test socket (e.g., ENPLAS FP-24(28)-1.27-07) for burn-in/testing.

In one embodiment, the I/O pad has the following signals with corresponding I/O pad description.

The V_{dd} pad has the V_{dd} signal, which is a 3.3V supply (range 3.0-3.6V); the Vₛₛ pad is the ground signal Gnd; V_{in[0-3.0]} is the amplifiers negative inputs; V_{out[0-3.0]} is the amplifiers positive inputs; en is the active high enable; and bias is the bias current input.

Accordingly, the amplifier of the present invention as described above, is superior to state-of-the-art commercial amplifiers, and has great commercial potential for use in military and space electronic components.

It should be emphasized that the above-described embodiments of the invention are merely possible examples of implementations set forth for a clear understanding of the principles of the invention. Variations and modifications may be made to the above-described embodiments of the invention without departing from the spirit and principles of the invention. All such modifications and variations are intended to be included herein within the scope of the invention and protected by the following claims.

What is claimed is:

1. An amplifier comprising:
a 0.25 μm complementary metal-oxide semiconductor (CMOS);
a 500 Krad total ionization dose and single event latchup immunity which is greater than the linear energy transfer (LET) 120 MeV-sq. cm/mg;
four channels of analog inputs;
enhanced low-dose rate sensitivity immunity;
a bias pin used to adjust quiescent current in a range of 1-35 μA; and
an active high enable pin en.

2. The amplifier of claim 1, wherein the amplifier is radiation-hardened.

3. The amplifier of claim 1, further comprising a 16-lead ceramic small-outline integrated circuit (SOIC) package in which the amplifier is disposed.

4. The amplifier of claim 1, further comprising a 3.0-3.6 V supply.

5. The amplifier of claim 1, wherein the amplifier is a four-channel mixed-signal Application Specific Integrated Circuit (ASIC).

6. The amplifier of claim 5, wherein the amplifier is an output rail-to-rail input/output (I/0) amplifier which can drive resistive loads down to 1 kOhm.

7. The amplifier of claim 6, further comprising:
an open loop direct current (DC) gain of 85 decibels (dB), unity gain bandwidth of 14 MHz, and 60 degrees phase margin.

8. The amplifier of claim 1, wherein an operating temperature is between −55° C. to 125° C., and is typically room temperature at 25° C.

9. The amplifier of claim 5, further comprising:
an external controller which operates the amplifier by setting said en and said bias pins.

10. The amplifier of claim 10, further requiring:
a 1 μF and a 10 μF capacitor for a supply voltage; and
one of a 1 μF or a 10 μF capacitor for said bias.
